(19) United States
(12) Patent Application Publication
(10) Pub. No.: US 2024/0274502 A1
(43) Pub. Date: Aug. 15, 2024

(54) Circuit Board Assembly and Connector Comprising the Same

(71) Applicants: Tyco Electronics (Shanghai) Co., Ltd., Shanghai (CN); Tyco Electronics AMP Qingdao Ltd., Qingdao (CN)

(72) Inventors: Jiefeng (Lear) Zhang, Shanghai (CN); Zhiqiang (Simon) Li, Shanghai (CN); Jinqiang (Jeff) Wang, Qingdao (CN); Guoxiao (Neo) Shen, Shanghai (CN); Wei (David) Zhao, Shanghai (CN); Guibin (Gabby) Lin, Foshan (CN)

(73) Assignees: Tyco Electronics (Shanghai) Co., Ltd., Shanghai (CN); Tyco Electronics AMP Qingdao Ltd., Qingdao (CN)

(21) Appl. No.: 18/439,848

(22) Filed: Feb. 13, 2024

(30) Foreign Application Priority Data
Feb. 13, 2023 (CN) 202320204131.6

(51) Int. Cl. H01L 23/40

(52) U.S. Cl. CPC H01L 23/4006; H01L 2023/4081; H01L 2023/4087

(57) ABSTRACT

A circuit board assembly includes a chip, a first loading board, a circuit board, an intermediate board and a second loading board. The first loading board is arranged on the chip, and the circuit board is electrically connected to the chip. The intermediate board is arranged on the circuit board and positions the chip. The second loading board is arranged on a side of the circuit board opposite the intermediate board. The second loading board includes a plurality of protrusions and indentations formed on a first side thereof opposing the circuit board.

### CROSS-REFERENCE TO RELATED APPLICATION

This application claims the priority of Chinese Patent Application No. CN 202320204131.6 filed on Feb. 13, 2023, the whole disclosure of which is incorporated herein by reference.

### FIELD OF THE INVENTION

The present disclosure relates to a circuit board assembly and a connector comprising the circuit board assembly.

### BACKGROUND

A connector is a device used to connect two active devices to transmit current or signals therebetween. A connector may simplify an assembly process of an electronic product, as well as simplify a mass production process of the electronic products. A connector also facilitates ease of repair, as a failed component may be quickly replaced. With the advancement of technology, an electronic product equipped with connector may be upgraded with new electronic components for improved performance, by way of example. A connector may enhance a flexibility of product design when designing and integrating a new product, as well as when creating a system with electronic components. Therefore, connectors are widely used in fields such as transportation, healthcare, aerospace, military, and home appliances.

The basic performances of a connector may be divided into three categories: mechanical performance, electrical performance, and environmental performance. Insertion and extraction force and mechanical life are important mechanical performance parameters. The insertion and extraction force and mechanical life of a connector are related to a structure of a contact (a magnitude of a positive pressure), a quality of a coating on a contact area (sliding friction coefficient), and an accuracy of a size of an arrangement of the contacts (alignment precision).

Main electrical performance parameters of a connector comprise a contact resistance, an insulation resistance, and a dielectric strength. Among them, a high-quality electrical connector should have a low and stable contact resistance, which ranges from a few milliohms to tens of milliohms. An insulation resistance is an index that measures the insulation performance between the contacts of an electrical connector and between the contacts and a housing of the connector. An order of magnitude of the insulation resistance ranges from hundreds of megaohms to thousands of megaohms. Dielectric strength is an ability of a connector to withstand a rated test voltage between the contacts of the connector or between the contacts and the housing. Finally, environmental performance comprises a temperature resistance, a humidity resistance, a salt spray resistance, a vibration and an impact resistance, etc.

Connectors are desired which provide and/or facilitate: high-speed and digitalization of signal transmission, integration of various signal transmissions, miniaturization of product volume, low cost of products, modular combination, and convenience of insertion and extraction, by way of example.

In a circuit board assembly commonly used for a connector, a backboard is a key component configured to form stable and reliable electrical connection between electrical components in the circuit board assembly. In practice, the backboard should be as lightweight and compact as possible, while also meeting the application requirements of high strength (i.e., able to provide greater loading force). However, in existing backboards, it is often necessary to increase the loading force by increasing a thickness of the backboard, which may, however, lead to an increase in the volume and weight of the backboard, making it difficult to meet the characteristics of miniaturization of the volume of the connector and low cost.

### SUMMARY

According to an embodiment of the present disclosure, a circuit board assembly includes a chip, a first loading board, a circuit board, an intermediate board and a second loading board. The first loading board is arranged on the chip, and the circuit board is electrically connected to the chip. The intermediate board is arranged on the circuit board and positions the chip. The second loading board is arranged on a side of the circuit board opposite the intermediate board. The second loading board includes a plurality of protrusions and indentations formed on a first side thereof opposing the circuit board.

### BRIEF DESCRIPTION OF THE DRAWINGS

The invention will now be described by way of example with reference to the accompanying Figures, of which:

FIG. 1 is a perspective view of a circuit board assembly according to an embodiment of the present disclosure;

FIG. 2 is a cross-sectional view of the circuit board assembly of FIG. 1;

FIG. 3 is a perspective view of the circuit board assembly of FIG. 1 with the first loading board removed therefrom, showing the chip installed therein;

FIG. 4 is a bottom view of the circuit board assembly of FIG. 1, showing the side of the second loading board away from the circuit board;

FIG. 5 is a perspective view of an individual second loading board of FIG. 4;

FIG. 6 is a cross-sectional view of the second loading board of FIG. 5; and

FIG. 7 is a perspective view of a second loading board according to another embodiment of the present disclosure.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION OF THE EMBODIMENTS

Exemplary embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

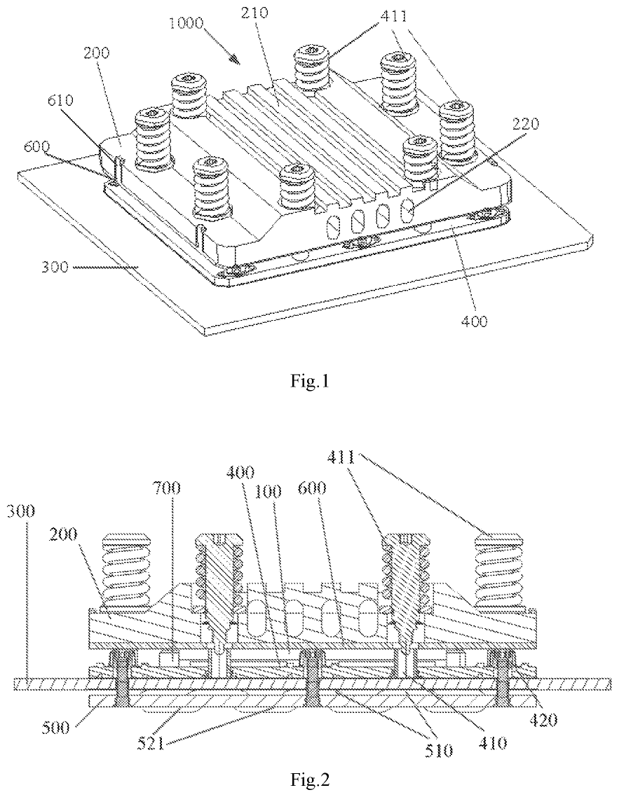

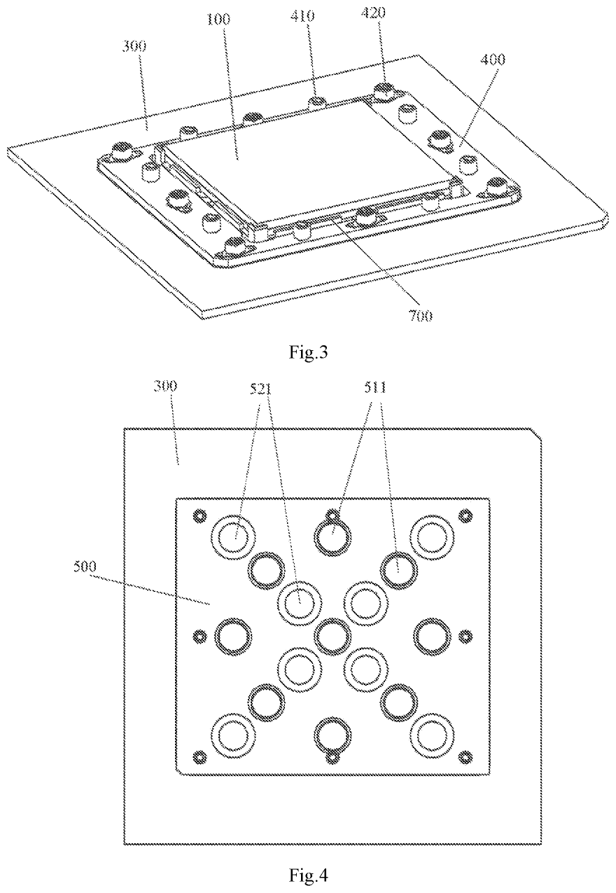

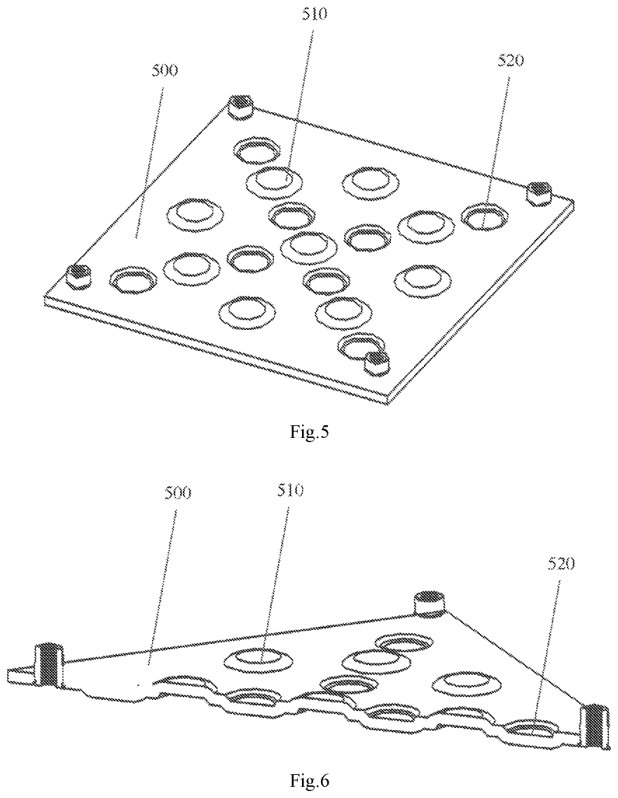

As shown in FIGS. 1-7, the present disclosure relates to a circuit board assembly 1000 for use in a connector. The assembly 1000 includes a chip 100, a first loading board 200, a circuit board 300, an intermediate board 400, and a second loading board 500 (also referred to as “backboard”). The first loading board 200 is provided with ribs 210 and channels 220 for dissipating heat from the chip 100. The circuit board 300 is electrically connected to the chip 100. The intermediate board 400 is installed on the circuit board 300 and is adapted to position the chip 100. The second loading board 500 is loaded or arranged on one side of the circuit board 300 away from the intermediate board 400.

The intermediate plate 400 is provided with first threaded holes 410 and second threaded holes 420 arranged alternately along its circumference. The first threaded holes 410 are adapted for use with spring bolts 411, and are used to attach the intermediate plate 400 to the first loading board 200 by a threaded connection. The second threaded holes 420 are used to attach the intermediate plate 400 to the second loading board 500 by a threaded connection. In this way, the intermediate plate 400 may simultaneously pull the first loading board 200 and the second loading board 500 in opposite directions. As a result, the chip 100 and the circuit board 300 are firmly sandwiched between the first loading board 200 and the second loading board 500, particularly when the circuit board assembly 1000 is subjected to external forces (for example, in an instance that vibration occurs). This ensures a safe, stable, and reliable electrical connection between the chip 100 and the circuit board 300.

The circuit board assembly 1000 also comprises a mounting part 600 and a mounting element 700 having a mounting groove. The mounting part 600 is provided with a snap arm 610 for snapping connection to the first loading board 200 and a recess for accommodating the chip 100. The intermediate board 400 is provided with a through hole in which the mounting element 700 is fixed to the circuit board 300. The intermediate board 400 is provided with a plurality of connection terminals that form electrical connections between the circuit board 300 and the chip 100.

When assembling the circuit board assembly 1000, the mounting part 600 is firstly snapped to the first loading board 200 through the snap arm 610, and then the chip 100 is fitted into the recess of the mounting part 600. In this way, the first loading board 200, the mounting part 600, and the chip 100 become a whole entity. A user may hold the first loading board 200 by hand or a robot may hold the first loading plate 200 by a mechanical arm to align the chip 100 with the mounting element 700 and install the chip 100 into the mounting groove of the mounting element, which greatly facilitates the assembly of the circuit board assembly 1000.

The second loading board 500 is provided with a plurality of protrusions 510 and indentations 520 on one side thereof against the circuit board 300, which are distributed alternately relative to each other. The alternating distribution of the protrusions 510 and the indentations 520 makes the distribution of loading force provided by the second loading board 500 more uniform.

The inclusion of the protrusions 510 and indentations 520 greatly increases the loading force, stiffness or capacity (e.g., overall strength) of the second loading board 500 without increasing a nominal thickness of the second loading board 500. The arrangement also reduces a material cost of the second loading board 500, as well as reducing a volume and a weight of the second loading board 500. As a result, the requirements of miniaturization of the volume and low cost of the connector, may be met.

In order to further increase the loading force or strength of the second loading board 500 and make the distribution of the loading force provided thereby more uniform, each of the protrusions 510 forms a corresponding indentation 511 on the opposite side of the second loading board 500. Likewise, each of the indentations 520 is forms a corresponding protrusion 521 on the opposite side of the second loading board 500.

The distribution of the protrusions 510 (and their corresponding indentations 511) and the indentations 520 (and their corresponding protrusion 521) on the second loading board 500 may be selected according to actual needs so as to obtain an expected distribution of the load or loading force. For example, the protrusions 510 and indentations 520 may be arranged on and/or within the boundary of at least one of the following shapes: a polygon (such as triangle, square, rectangle, pentagon, etc.), a circle or an ellipse.

Referring to the embodiment shown in FIGS. 4-6, the protrusions 510 and indentations 520 may be distributed on and/or within the boundary of a square. For example, the second loading board 500 comprises four indentations 520 respectively located at four vertices of the square and four protrusions 510 respectively located at midpoints of four side edges of the square. The second loading board 500 further comprises three additional protrusions 510 located between two indentations 520 on each diagonal of the square and two additional indentations 520 located between every adjacent two of the three additional indentations 520.

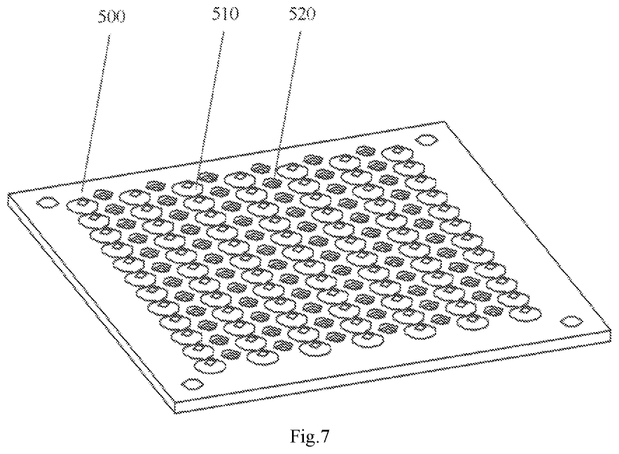

The protrusions 510 and the indentations 520 may also be arranged in a matrix. Referring to the embodiment in FIG. 7, the second loading board 500 comprises protrusions 510 arranged in columns and indentations 520 arranged in columns, which are alternately distributed relative to each other. In another embodiment wherein the protrusions 510 and indentations 520 are arranged in a matrix, the protrusions 510 and indentations 520 may be arranged alternately in each of both row and column directions.

In addition, those areas in which it is believed that those of ordinary skill in the art are familiar, have not been described herein in order not to unnecessarily obscure the invention described. Accordingly, it has to be understood that the invention is not to be limited by the specific illustrative embodiments, but only by the scope of the appended claims.

It should be appreciated for those skilled in this art that the above embodiments are intended to be illustrated, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and proceeded with the word “a” or “an” should be understood as not excluding plural of the elements or steps, unless such exclusion is explicitly stated. Furthermore, references to “one embodiment” of the present disclosure are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. A circuit board assembly comprising:
a chip;
a first loading board arranged on the chip;
a circuit board electrically connected to the chip;
an intermediate board arranged on the circuit board and positioning the chip; and
a second loading board arranged on a side of the circuit board opposite the intermediate board, the second loading board including a plurality of protrusions and indentations formed on a first side thereof opposing the circuit board.

2. The circuit board assembly according to claim 1, wherein the plurality of protrusions and indentations are distributed alternately relative to each other.

3. The circuit board assembly according to claim 1, wherein each of the protrusions forms a corresponding indentation on an opposite second side of the second loading board.

4. The circuit board assembly according to claim 3, wherein each of the indentations forms a corresponding protrusion on the opposite second side of the second loading board.

5. The circuit board assembly according to claim 1, wherein the plurality of protrusions and indentations are arranged at least one of on or within a boundary of at least one of a shape of a polygon, a circle, or an ellipse.

6. The circuit board assembly according to claim 5, wherein the second loading board comprises four of the indentations respectively located on the first side at four vertices of a square and four of the protrusions respectively located at midpoints of four side edges of the square.

7. The circuit board assembly according to claim 6, wherein the second loading board further comprises three additional protrusions on the first side between two indentations on each diagonal of the square and two additional indentations located on the first side between every adjacent two of the three additional indentations.

8. The circuit board assembly according to claim 4, wherein the protrusions and indentations are arranged in a matrix, in which columns of the protrusions and columns of the indentations are alternately arranged relative to each other.

9. The circuit board assembly according to claim 1, wherein the intermediate plate is provided with a plurality of first threaded holes and second threaded holes arranged alternately along its circumference.

10. The circuit board assembly according to claim 9, wherein the first threaded holes attach the intermediate plate to the first loading board by respective first threaded connections.

11. The circuit board assembly according to claim 10, wherein the second threaded holes attach the intermediate plate to the second loading board by respective second threaded connections.

12. The circuit board assembly according to claim 11, wherein the first threaded connections attaching the intermediate plate to the first loading board include spring bolts.

13. The circuit board assembly according to claim 12, therein each spring bolt includes a compression spring arranged on a side of the first loading board opposite the intermediate plate.

14. The circuit board assembly according to claim 1, further comprising a mounting part including with a snap arm forming a snapping connection to the first loading board and a recess accommodating the chip.

15. The circuit board assembly according to claim 14, further comprising a mounting element defining a mounting groove and fixed to the circuit board within a through hole formed in the intermediate board.

16. The circuit board assembly according to claim 15, wherein the intermediate board includes a plurality of connection terminals forming electrical connections between the circuit board and the chip.

17. A circuit board assembly comprising:
a chip;
a first loading board arranged on the chip;
a circuit board electrically connected to the chip;
an intermediate board arranged on the circuit board and positioning the chip; and
a second loading board arranged on a side of the circuit board opposite the intermediate board, the second loading board including a plurality of protrusions and indentations formed on a first side thereof opposite the circuit board.

18. The circuit board assembly according to claim 17, wherein:
each of the protrusions forms a corresponding indentation on a second side of the second loading board opposing the circuit board; and
each of the indentations forms a corresponding protrusion on the second side of the second loading board.

19. The circuit board assembly according to claim 17, wherein the intermediate plate is attached to the first loading board via a plurality of spring bolts.

20. The circuit board assembly according to claim 17, wherein the intermediate plate is attached to the second loading board via respective threaded connections.
